(19) United States
(12) Patent Application Publication
(10) Pub. No.: US 2026/0223392 A1
(43) Pub. Date: Jul. 30, 2026

(54) SEMICONDUCTOR DEVICE, METHOD FOR MONITORING PROPAGATION LENGTH, AND METHOD FOR MANUFACTURING SEMICONDUCTOR DEVICE

(71) Applicant: RENESAS ELECTRONICS CORPORATION, Tokyo (JP)

(72) Inventor: Yanzhe WANG, Tokyo (JP)

(21) Appl. No.: 19/404,326

(22) Filed: Dec. 1, 2025

(30) Foreign Application Priority Data
Jan. 24, 2025 (JP) 2025-010529

(51) Int. Cl. H10D 30/66; G01R 31/26; H10D 30/01; H10D 62/80; H10D 62/83; H10D 62/832; H10D 62/85

(52) U.S. Cl. CPC H10D 30/66; G01R 31/2644; G01R 31/2648; H10D 30/0291; H10D 62/8303; H10D 62/8325; H10D 62/8503; H10D 62/875

(57) ABSTRACT

Provide a technology that can estimate a propagation length. An evaluation element includes a diffusion layer formed in a semiconductor substrate and a plurality of a pair of contacts electrically connected to the diffusion layer. The plurality of the pair of contacts are separated by a distance in the X direction. A width of the third contacts in the X direction is smaller than a width of a second contacts in the X direction. The width of the second contacts is smaller than a width of the first contacts in the X direction.

### CROSS-REFERENCE TO RELATED APPLICATIONS

The disclosure of Japanese Patent Application No. 2025-010529 filed on January 24, 2025, including the specification, drawings and abstract is incorporated herein by reference in its entirety.

### BACKGROUND

The present invention relates to a semiconductor device, a method for monitoring a propagation length, and a method for manufacturing a semiconductor device. In particular, it pertains to a semiconductor device equipped with an evaluation element, a method for monitoring the propagation length using a semiconductor device, and a method for manufacturing a semiconductor device using a method for monitoring the propagation length.

As described in Japanese Unexamined Patent Application Publication No. 2008-277769 (Patent Document 1), a method is employed where an evaluation element is prepared to measure a resistance between multiple contacts, and the measurement results from the evaluation element are fed back to the mass production line.

Additionally, as a method for measuring the characteristics of semiconductor elements such as a MOSFET (Metal Oxide Semiconductor Field Effect Transistors), a TLM (Transfer Length Method) is known. In the TLM method, while varying the spacing between a pair of contacts, a contact resistance at the points where the contacts and the diffusion layer are in contact, and the resistance of the diffusion layer connecting the pair of contacts are measured, and the propagation length is calculated from these measurement results.

### SUMMARY

Typically, the propagation length is calculated on the assumption that a sheet resistance of the contact and the sheet resistance of a diffusion layer are equivalent. Therefore, if the sheet resistance of the contact and the sheet resistance of the diffusion layer differ, the conventional method cannot calculate the propagation length. When a width of the contact becomes smaller than the propagation length, the contact resistance increases, and an on-resistance of the MOSFET increases. Consequently, there is a risk of degrading the performance of the semiconductor device.

Other objects and novel features will become apparent from the description of this specification and the accompanying drawings.

A semiconductor device in one embodiment includes an evaluation element. The evaluation element comprises the diffusion layer formed in a semiconductor substrate, and a pair of first contacts, a pair of second contacts, and a pair of third contacts electrically connected to the diffusion layer. The pair of first contacts are spaced apart by a first distance in a first direction in a plan view. The pair of second contacts are spaced apart by the first distance in the first direction. The pair of third contacts are spaced apart by the first distance in the first direction. A third width of the third contacts in the first direction is smaller than a second width of the second contacts in the first direction. The second width is smaller than a first width of the first contacts in the first direction.

According to one embodiment, it is possible to estimate the propagation length. Additionally, the performance of the semiconductor device can be improved.

### BRIEF DESCRIPTION OF THE DRAWINGS

FIG. 1 is a perspective view showing an overview of an evaluation element used in a TLM method.

FIG. 2 is an equivalent circuit diagram of FIG. 1.

FIG. 3 is a graph showing the measurement results by the TLM method.

FIG. 4 is a plan view showing the evaluation element in the first embodiment.

FIG. 5 is a cross-sectional view showing the evaluation element in the first embodiment.

FIG. 6 is a graph showing the measurement results by the TLM method in the first embodiment.

FIG. 7 is a plan view showing a wafer and the form of the semiconductor device in the first embodiment.

FIG. 8 is a cross-sectional view showing a manufacturing process of the semiconductor device in the first embodiment.

FIG. 9 is a cross-sectional view showing a manufacturing process of the semiconductor device following FIG. 8.

FIG. 10 is another cross-sectional view showing a manufacturing process of the semiconductor device following FIG. 8.

FIG. 11 is a cross-sectional view showing a manufacturing process of the semiconductor device following FIG. 9.

FIG. 12 is a cross-sectional view showing a manufacturing process of the semiconductor device following FIG. 11.

FIG. 13 is another cross-sectional view showing a manufacturing process of the semiconductor device following FIG. 11.

FIG. 14 is a cross-sectional view showing a manufacturing process of the semiconductor device following FIG. 12.

FIG. 15 is another cross-sectional view showing a manufacturing process of the semiconductor device following FIG. 12.

FIG. 16 is a cross-sectional view showing a manufacturing process of the semiconductor device following FIG. 14.

FIG. 17 is a cross-sectional view showing a manufacturing process of the semiconductor device following FIG. 16.

FIG. 18 is another cross-sectional view showing a manufacturing process of the semiconductor device following FIG. 16.

FIG. 19 is a cross-sectional view showing a manufacturing process of the semiconductor device following FIG. 17.

### DETAILED DESCRIPTION

Hereinafter, embodiments will be described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In addition, an X direction, a Y direction, and a Z direction described in this application intersect each other and are orthogonal to each other. In this application, the Z direction is a vertical direction, depth direction, or thickness direction of a certain structure. Also, the expressions such as "plan view" or "in plan" used in this application mean that the plane formed by the X direction and the Y direction is a "plane" and the "plane" is viewed from the Z direction.

### FIRST EMBODIMENT

### Findings Obtained by the Inventors

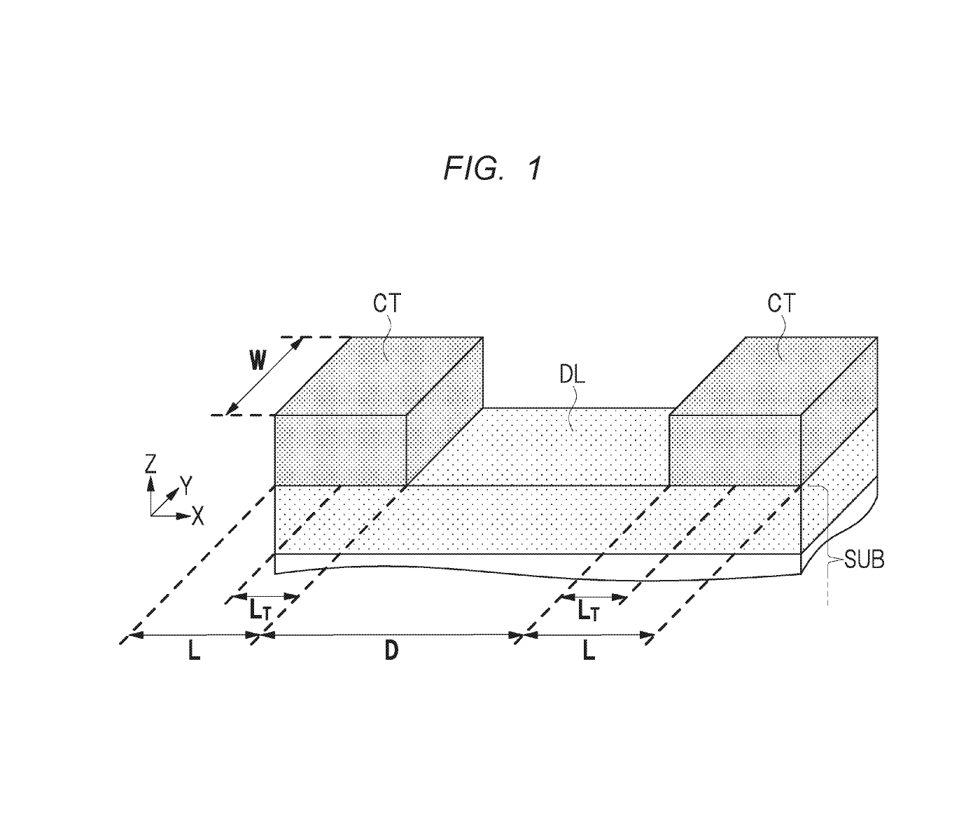

First, the new findings obtained by the inventors of this application will be described with reference to FIG. 1 to FIG. 3.

FIG. 1 shows an outline of an evaluation element used in a TLM method. As shown in FIG. 1, a diffusion layer DL is formed in a semiconductor substrate SUB. The diffusion layer DL is an impurity region having n-type or p-type conductivity. A pair of contacts CT are formed on the diffusion layer DL. The contacts CT are made of a conductive film such as a metal film.

The contacts CT have a width W in the Y direction and a width L in the X direction. The pair of contacts CT are separated by a distance D in the X direction. Here, the propagation length LT is shorter than the width L.

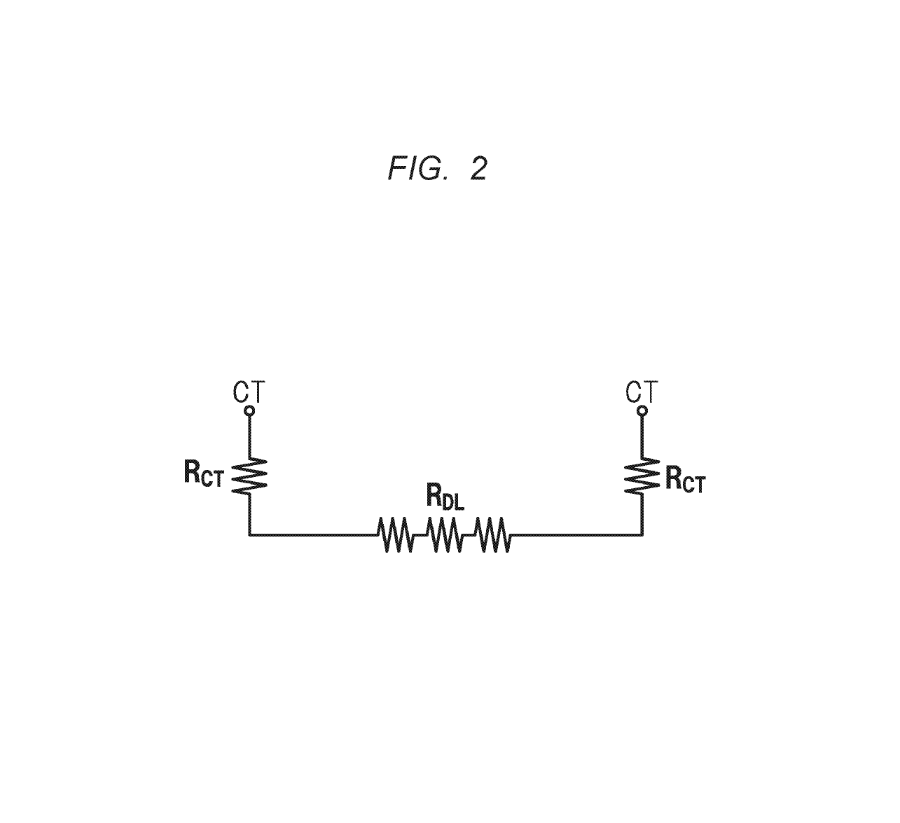

FIG. 2 is an equivalent circuit diagram of FIG. 1. A contact resistance RCL is a contact resistance of the contact CT and the diffusion layer DL, and a diffusion resistance RDL is a resistance of the diffusion layer DL connecting the pair of contacts CT.

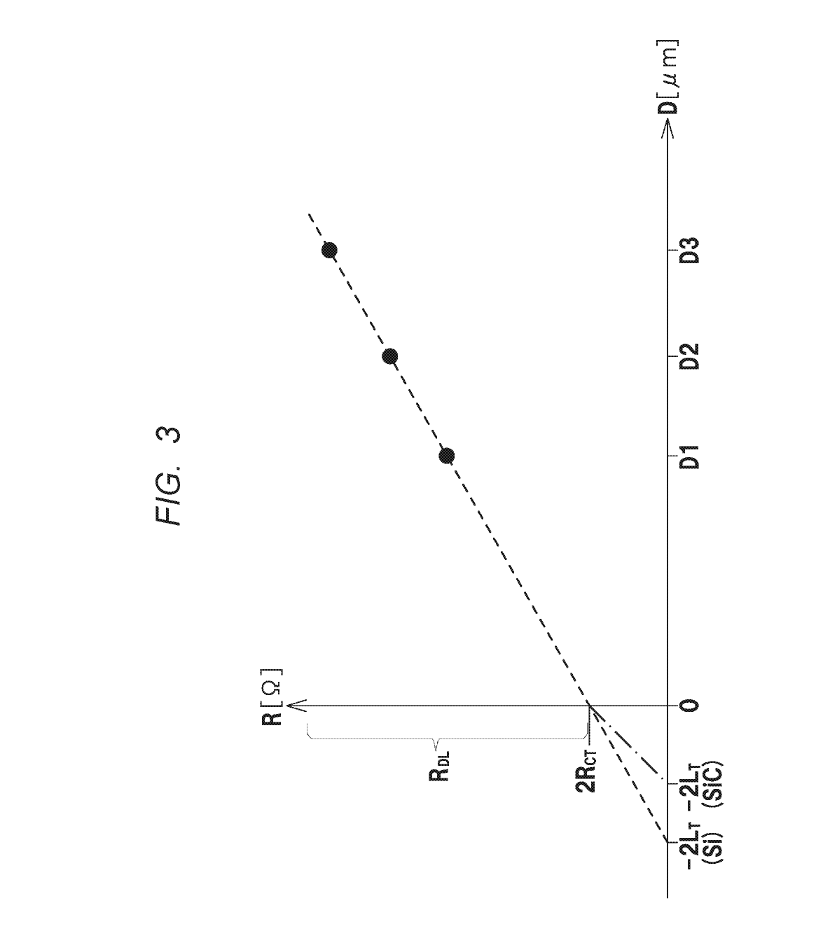

As shown in FIG. 3, when the semiconductor substrate SUB is made of silicon (Si), it is assumed that a sheet resistance of the contact CT and a sheet resistance of the diffusion layer DL are equivalent, so by changing the distance D, the propagation length LT can be estimated.

In recent years, semiconductor devices equipped with a MOSFET formed on a compound semiconductor substrate such as a silicon carbide (SiC) substrate is widely used. SiC has an electric field strength for dielectric breakdown that is about an order of magnitude greater than that of Si. Therefore, in a power MOSFET using SiC substrates, a drift region that maintains the breakdown voltage can be made about 1/10 thinner, and the impurity concentration can be increased by about 100 times, theoretically reducing an element resistance by more than three orders of magnitude. Furthermore, since the bandgap of SiC is about three times larger than that of Si, the power MOSFET using SiC substrates can operate at high temperatures.

Here, the inventors of this application have found that when the semiconductor substrate SUB is made of SiC, the sheet resistance of the contact CT is greater than the sheet resistance of the diffusion layer DL, and an actual propagation length LT becomes smaller than an estimated propagation length LT assuming the semiconductor substrate SUB is a Si substrate. Additionally, when the diffusion layer DL is p-type, the propagation length LT becomes even smaller.

Factors for the propagation length LT being estimated as smaller include differences in the physical properties of SiC and Si, and the interface state between the SiC substrate and the film, such as a silicide film, formed on the SiC substrate, which tends to deteriorate more easily compared to a Si substrate.

Moreover, similar phenomena occur not only in SiC substrates but also when the semiconductor substrate SUB is made of a wide bandgap semiconductor with a bandgap wider than that of Si. For example, similar phenomena occur when the semiconductor substrate SUB is made of materials including gallium nitride, gallium oxide, or diamond.

### Evaluation Element

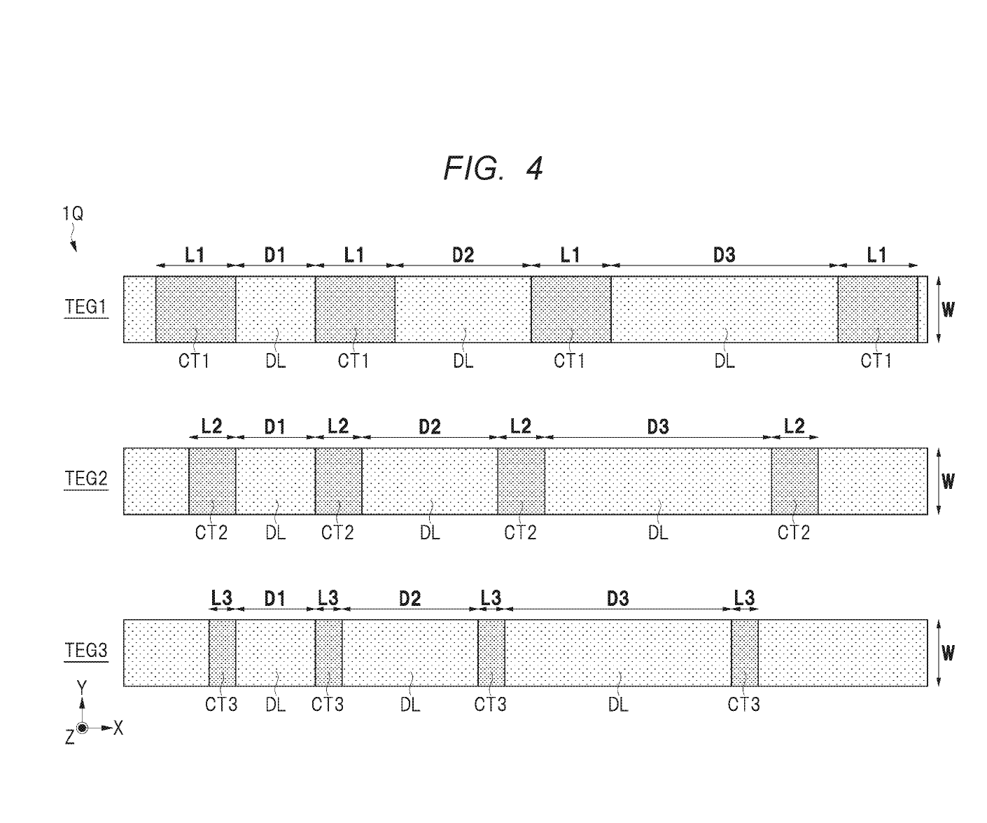

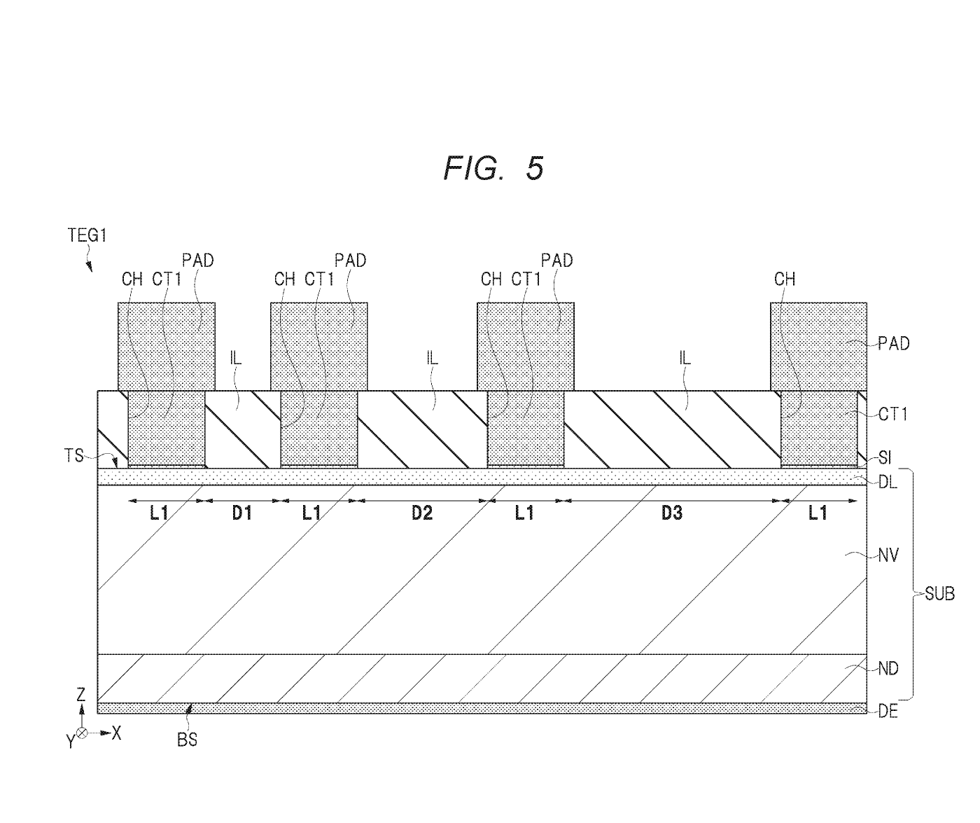

FIG. 4 and FIG. 5 show the evaluation element 1Q devised by the inventors of this application in consideration of the above findings. As shown in FIG. 4, the evaluation element 1Q includes at least three evaluation patterns (evaluation pattern TEG1, evaluation pattern TEG2, evaluation pattern TEG3).

FIG. 5 represents a cross-sectional view of the evaluation pattern TEG1 among the evaluation pattern TEG1, evaluation pattern TEG2, and evaluation pattern TEG3.

As shown in FIG. 4 and FIG. 5, the evaluation pattern TEG1 includes the diffusion layer DL formed in the semiconductor substrate SUB, an interlayer insulating film IL formed on the diffusion layer DL, a plurality of contacts CT1, and a plurality of pad electrodes PAD.

The semiconductor substrate SUB is made of a wide bandgap semiconductor with a bandgap wider than that of Si, and is made of, for example, SiC, materials including gallium nitride, gallium oxide, or diamond. In the following description, the case where the semiconductor substrate SUB is made of SiC is exemplified as a representative. The diffusion layer DL is an impurity region formed in the semiconductor substrate SUB and has n-type or p-type conductivity. The interlayer insulating film IL is, for example, a silicon oxide film.

A plurality of holes CH is formed in the interlayer insulating film IL. By embedding a first conductive film in the plurality of holes CH, the plurality of contacts CT1 are formed in the interlayer insulating film IL. The plurality of contacts CT1 is electrically connected to the diffusion layer DL. The first conductive film consists of a first barrier metal film and a first metal film formed on the first barrier metal film. The first barrier metal film is, for example, a titanium nitride film. The first metal film is, for example, a tungsten film.

The plurality of pad electrodes PAD is formed on the interlayer insulating film IL and are electrically connected to the plurality of contacts CT1. The pad electrode PAD is provided to contact the terminals of the test device when measuring an electrical resistance between the pair of contacts CT1.

The plurality of pad electrodes PAD is made of a second conductive film. The second conductive film consists of a second barrier metal film and a second metal film formed on the second barrier metal film. The second barrier metal film is, for example, a titanium nitride film. The second metal film is, for example, an aluminum alloy film to which copper or silicon is added.

Here, although the case where the contact CT1 and the pad electrode PAD are composed of separate conductive films is exemplified, the contact CT1 and the pad electrode PAD may be made of the same second conductive film and may be integrated. In that case, the second conductive film formed on the interlayer insulating film IL constitutes the pad electrode PAD, and the second conductive film embedded in the hole CH constitutes the contact CT1.

A silicide film SI may be formed between each of the plurality of contacts CT1 and the diffusion layer DL. The silicide film SI is, for example, a nickel silicide film, cobalt silicide film, or titanium silicide film.

Each of the plurality of contacts CT1 has a width W in the Y direction and a width L1 in the X direction. Here, the case where the width in the Y direction of the diffusion layer DL is the same width W as the contact CT1 is exemplified. The plurality of contacts CT1 is formed such that the distance D between two adjacent contacts CT1 in the X direction is different. A distance D1 is, for example, 5 micrometers or more and is smaller than a distance D2. The distance D2 is smaller than a distance D3.

The structure of the evaluation pattern TEG2 or the evaluation pattern TEG3 is the same as the structure of the evaluation pattern TEG1 except that the contact CT1 is replaced with the contact CT2 or contact CT3, and the width L1 is changed to a width L2 or a width L3. The width L3 is smaller than the width L2, and the width L2 is smaller than the width L1.

### Method for Monitoring Propagation Length

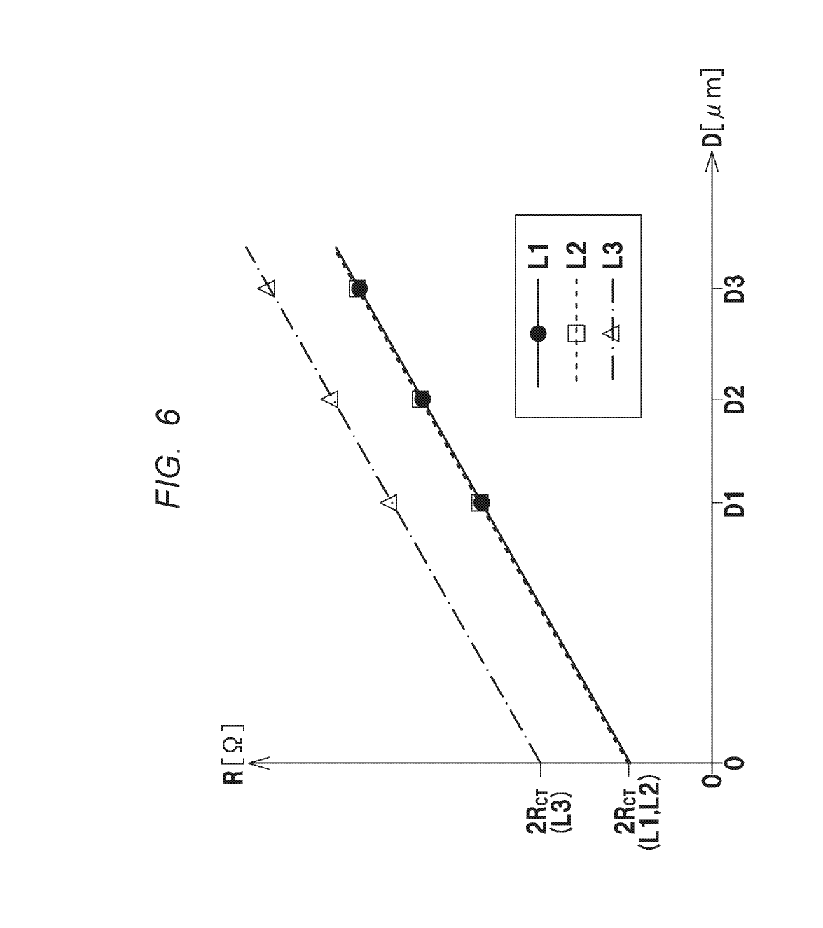

The method for monitoring the propagation length LT using the evaluation element 1Q will be described below with reference to FIG. 4 and FIG. 6.

First, in the pair of contacts CT1 separated by distances D1, D2 and D3, the electrical resistance of a path from one contact CT1 to the other contact CT1 via the diffusion layer DL is measured. Next, in a pair of contacts CT2 separated by the distances D1, D2 and D3, an electrical resistance of a path from one contact CT2 to the other contact CT2 via the diffusion layer DL is measured. Next, in a pair of contacts CT3 separated by the distances D1, D2 and D3, an electrical resistance of a path from one contact CT3 to the other contact CT3 via the diffusion layer DL is measured.

FIG. 6 shows an example of the results of measuring each electrical resistance. In FIG. 6, it is shown that there is no change in the electrical resistance of the width L1 and the electrical resistance of the width L2, and there is a change in the electrical resistance of the width L2 and the electrical resistance of the width L3.

The distances D1, D2 and D3 of the evaluation pattern TEG1 are the same as the distances D1, D2 and D3 of the evaluation pattern TEG2, and the same as the distances D1, D2 and D3 of the evaluation pattern TEG3. Therefore, in the evaluation patterns TEG1, TEG2 and TEG3, the diffusion resistance RDL is the same. Therefore, a change in electrical resistance means that the contact resistance RCL is changing, and the width L of the contact is smaller than the propagation length LT.

That is, the fact that there is no change in the electrical resistance of the width L1 and the electrical resistance of the width L2 means that the propagation length LT can be determined to be smaller than the width L2. And the fact that there is a change in the electrical resistance of the width L2 and the electrical resistance of the width L3 means that the propagation length LT can be determined to be larger than the width L3. Therefore, from the relationship "width L3 < propagation length LT < width L2," the propagation length LT can be estimated.

If there is no change in the electrical resistance of the width L1 and the width L2, and no change in the electrical resistance of the width L2 and the width L3, the propagation length LT can be determined to be smaller than the width L3 (propagation length LT < width L3). If there is a change in the electrical resistance of the width L1 and the width L2, the propagation length LT can be determined to be smaller than the width L1 and larger than the width L2 (width L2 < propagation length LT < width L1).

Thus, according to the first embodiment, even if the semiconductor substrate SUB is made of a wide bandgap semiconductor with a wider bandgap than Si, and the sheet resistance of the contact CT and the sheet resistance of the diffusion layer DL are different, the propagation length LT can be estimated by using the evaluation patterns TEG1, TEG2 and TEG3 with different widths L.

In FIG. 4, three types of evaluation patterns such as evaluation patterns TEG1, TEG2 and TEG3 are illustrated, and three types of widths L such as the widths L1, L2 and L3 are illustrated, but the evaluation patterns and the widths L may each be four or more types. The more types of evaluation patterns and the widths L there are, the more accurately the propagation length LT can be estimated. In FIG. 4, three types of distances D such as the distances D1, D2 and D3 are illustrated, but the distance D may be four or more types.

### Manufacturing Method of Semiconductor Device

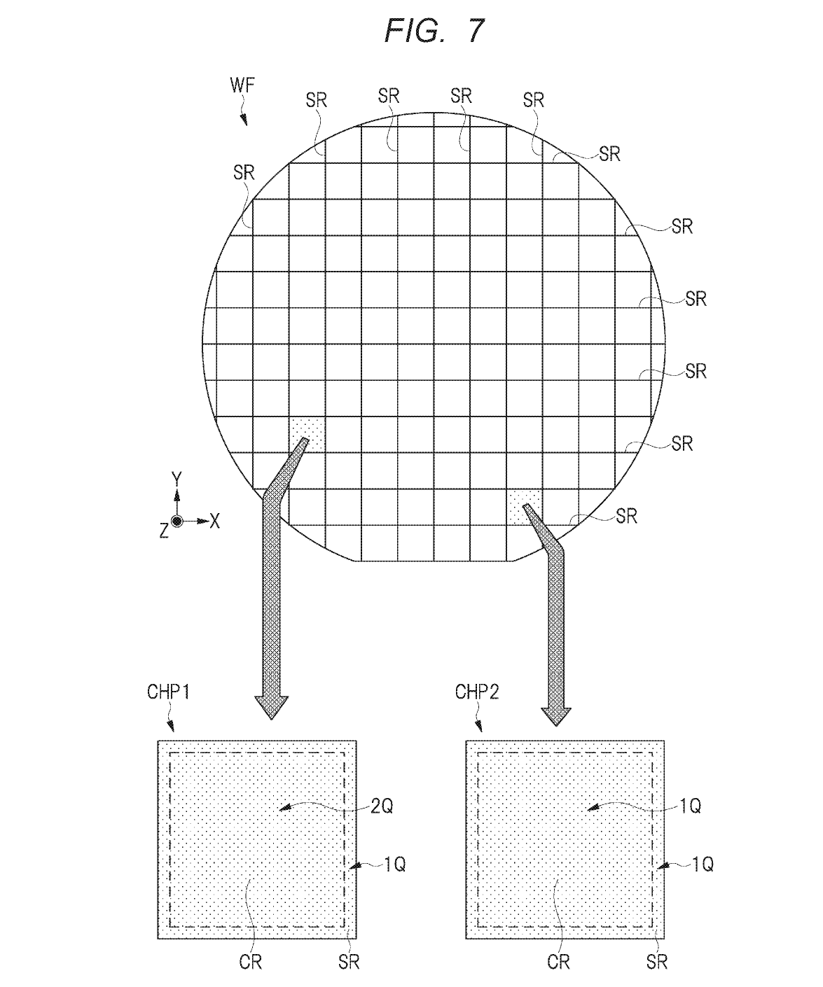

The manufacturing steps included in the manufacturing method of the semiconductor device using a monitoring method of the propagation length LT will be described below with reference to FIGS. 7 to 19. The value of the propagation length LT determined by the monitoring method of the above-mentioned propagation length LT can be fed back to each manufacturing step.

FIG. 7 shows a wafer WF, semiconductor chip CHP1 and semiconductor chip CHP2. By dicing the completed wafer WF along a scribe area SR by a dicing process, a plurality of semiconductor chips CHP1 and a plurality of semiconductor chips CHP2 are obtained.

As a form of the semiconductor device in the first embodiment, the semiconductor chips CHP1 and CHP2 are illustrated. The semiconductor chip CHP1 is a chip for product shipment. The semiconductor chip CHP2 is an evaluation chip not for product shipment. Each of the semiconductor chips CHP1 and CHP2 has a cell region CR and the scribe area SR surrounding the cell region CR in plan view.

In the semiconductor chip CHP1, the evaluation element 1Q is provided in the scribe area SR, and, for example, a MOSFET 2Q is provided in the cell region CR. In the semiconductor chip CHP2, various test elements including the evaluation element 1Q are provided in the scribe area SR and the cell region CR.

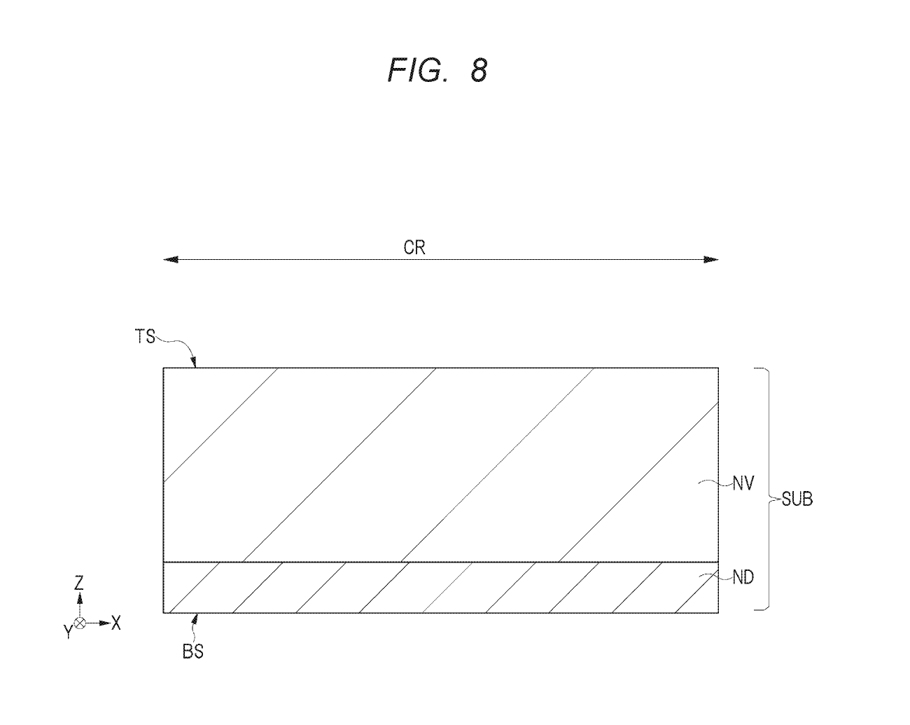

In the manufacturing steps described below with reference to FIGS. 8 to 19, the case where the semiconductor device is the semiconductor chip CHP1 is illustrated. In the following, the structure of the cell region CR will mainly be described, but the structure of the scribe area SR will also be described as necessary. The impurity showing n-type conductivity is, for example, nitrogen, and the impurity showing p-type conductivity is, for example, aluminum.

As shown in FIG. 8, an n-type semiconductor substrate SUB having an upper surface TS and a bottom surface BS, and made of SiC is prepared. The semiconductor substrate SUB has an n-type drain region ND and an n-type drift region NV formed on the drain region ND. The impurity concentration of the drain region ND is higher than the impurity concentration of the drift region NV.

The semiconductor substrate SUB may be a laminated body of an n-type SiC substrate and an n-type SiC layer formed on the n-type SiC substrate by an epitaxial growth method. In that case, the n-type SiC substrate constitutes the drain region ND, and the n-type SiC layer constitutes the drift region NV.

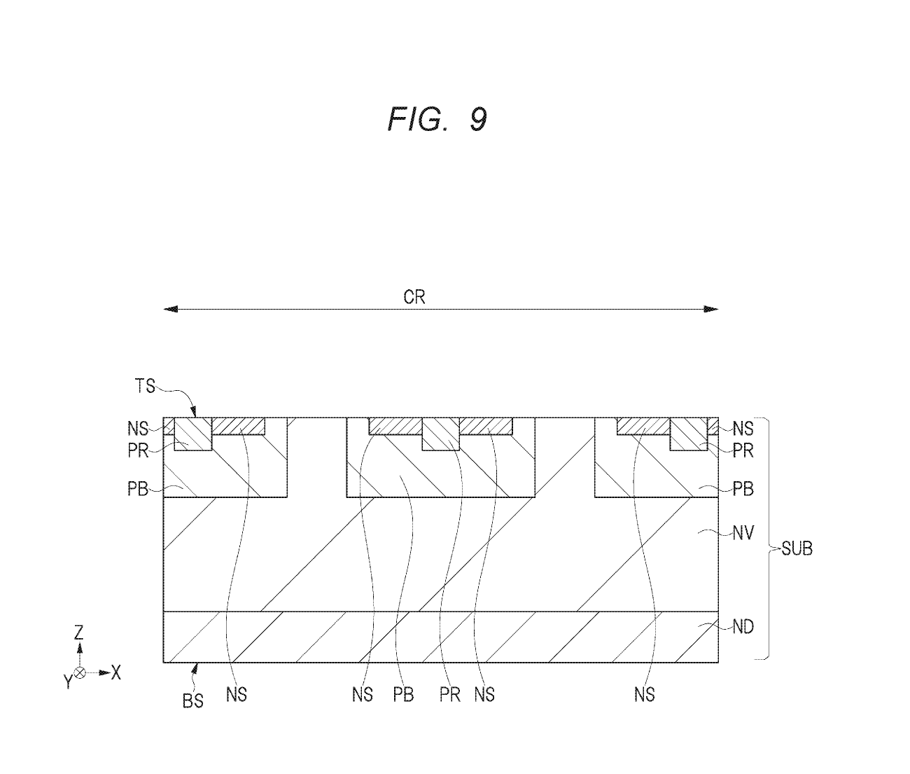

As shown in FIG. 9, first, a plurality of p-type body regions PB is selectively formed in the semiconductor substrate SUB in the cell region CR by photolithography and ion implantation process es. Next, an n-type source region NS is selectively formed in the body region PB by photolithography and ion implantation methods. Next, a p-type high-concentration diffusion region PR is selectively formed in the body region PB by photolithography and ion implantation processes.

The impurity concentration of the source region NS is higher than the impurity concentration of the drift region NV. The impurity concentration of the high-concentration diffusion region PR is higher than the impurity concentration of the body region PB. The body region PB is formed from the upper surface TS of the semiconductor substrate SUB to a predetermined depth. The source region NS and the high-concentration diffusion region PR are each formed to be shallower than the body region PB from the upper surface TS of the semiconductor substrate SUB.

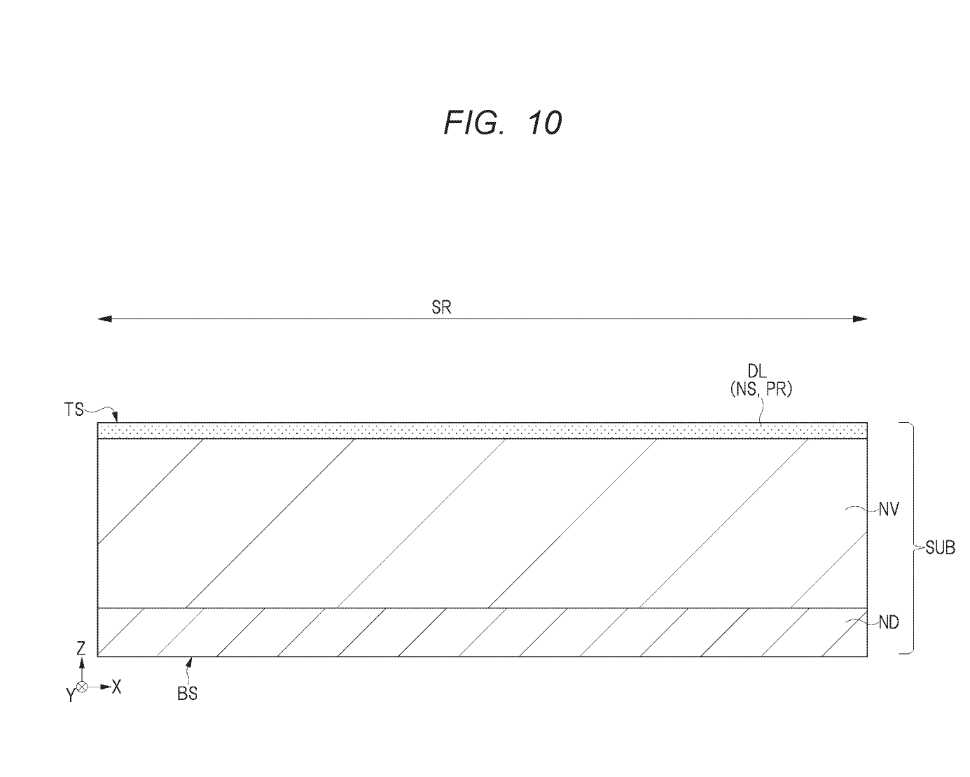

In the scribe area SR, as shown in FIG. 10, the diffusion layer DL is selectively formed in the semiconductor substrate SUB by photolithography and ion implantation processes. When forming an n-type diffusion layer DL, the diffusion layer DL may be formed by the same manufacturing process as the source region NS. When forming a p-type diffusion layer DL, the diffusion layer DL may be formed by the same manufacturing process as the high-concentration diffusion region PR.

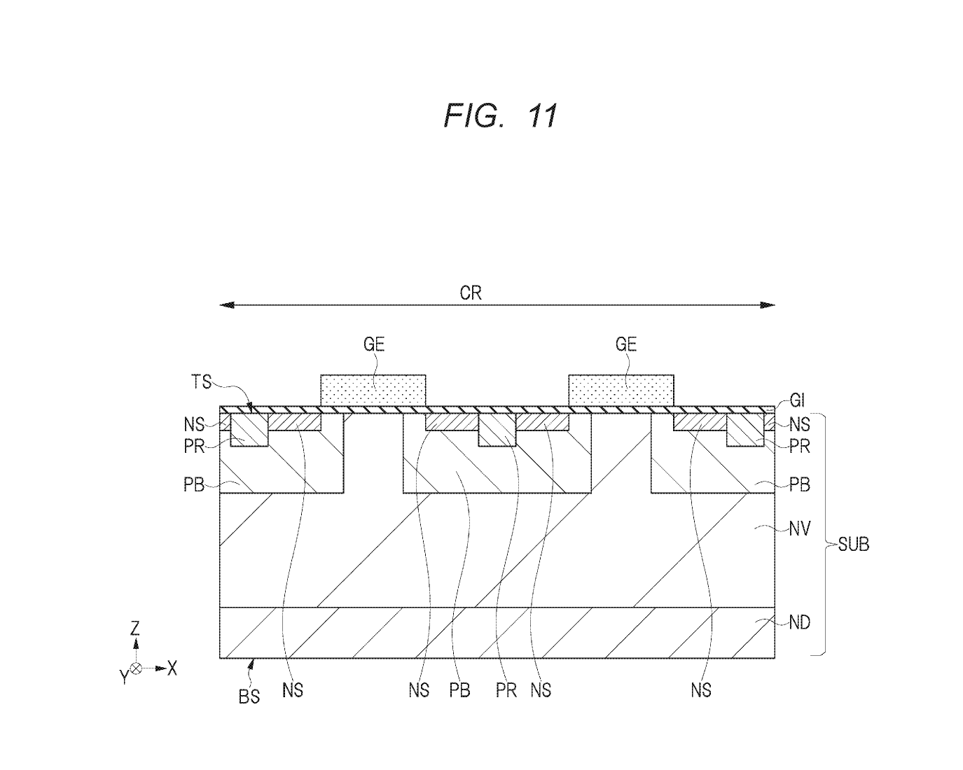

After the manufacturing steps of FIGS. 9 and 10, as shown in FIG. 11, first, a gate dielectric film GI is formed on the upper surface TS of the semiconductor substrate SUB by, for example, thermal oxidation treatment. The gate dielectric film GI is, for example, a silicon oxide film. Next, the conductive film is formed on the gate dielectric film GI by a film forming process using, for example, a CVD method. The conductive film is, for example, a polysilicon film in which n-type impurities are introduced.

Next, by patterning the conductive film, a plurality of gate electrodes GE is formed on the gate dielectric film GI in the cell region CR. The gate electrode GE is formed to straddle a part of each of two adjacent body regions PB and the drift region NV located between the two adjacent body regions PB.

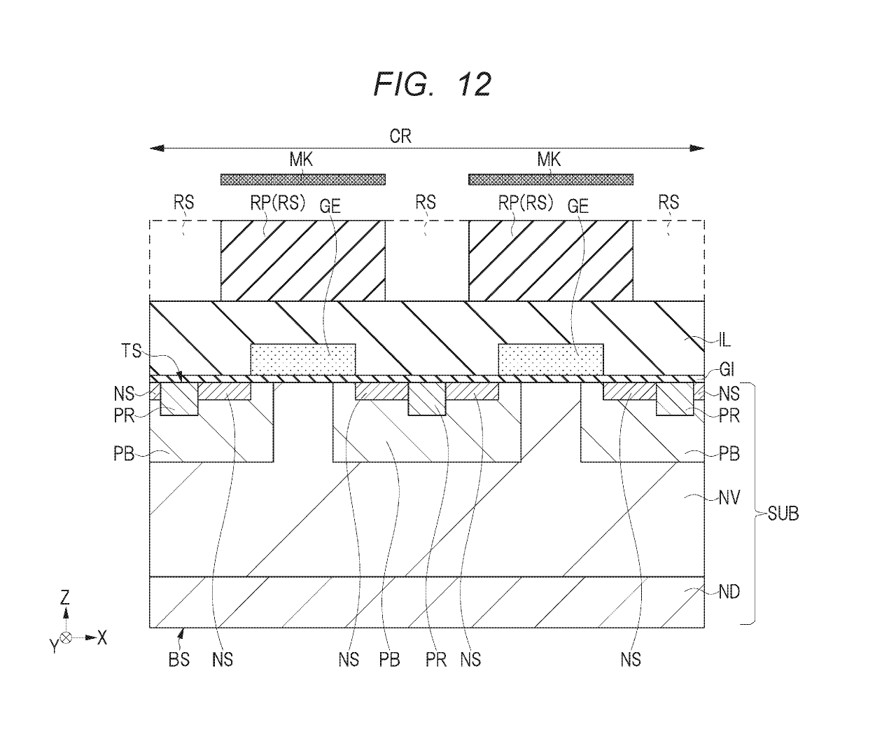

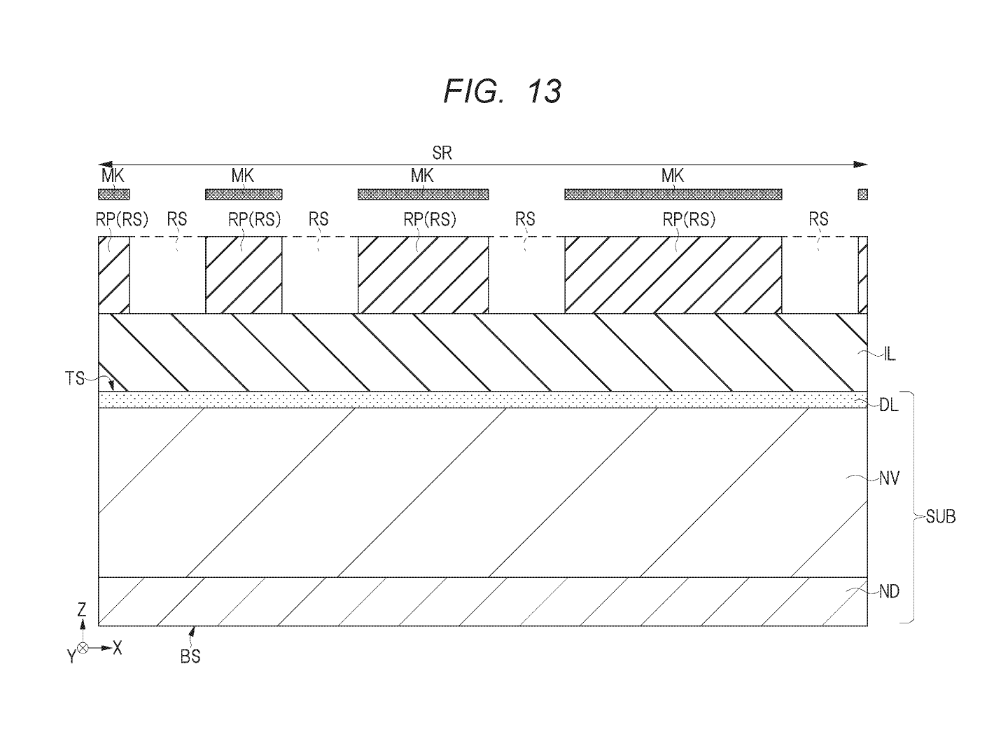

As shown in FIGS. 12 and 13, first, the interlayer insulating film IL is formed on the upper surface TS of the semiconductor substrate SUB by a film forming process using, for example, a CVD method so as to cover the plurality of gate electrodes GE. Next, a resist material RS is formed on the interlayer insulating film IL. Next, an exposure mask MK having various pattern shapes is prepared.

Next, by performing a photolithography process on the resist material RS using the exposure mask MK, a part of the resist material RS is selectively removed to form a resist pattern RP. Here, the case where the resist material RS is positive type and the exposed portion is selectively removed is illustrated. However, the resist material RS may be negative type, and the unexposed portion may be selectively removed.

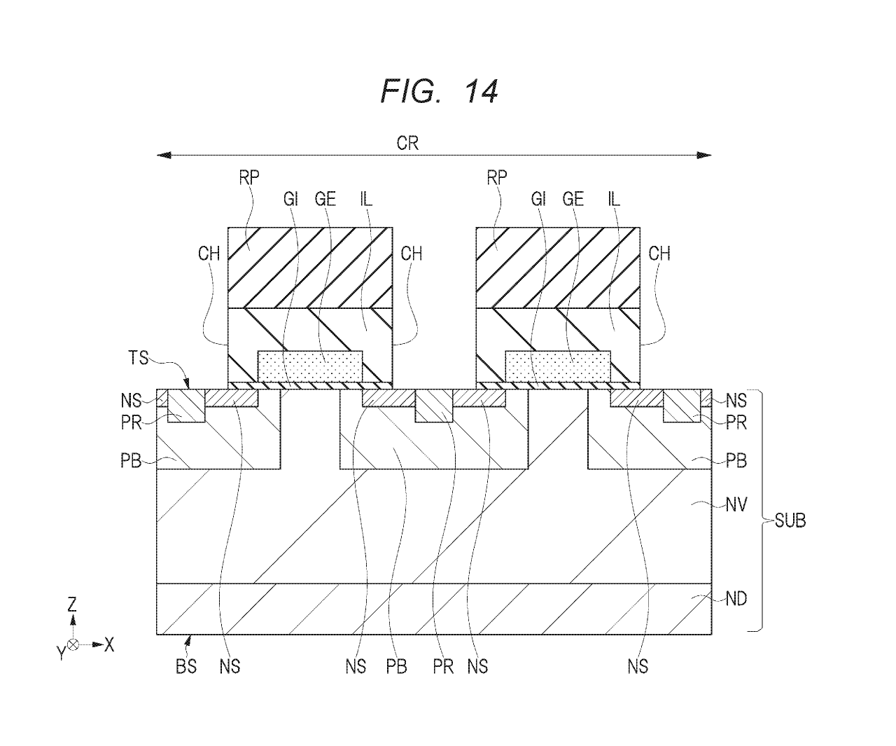

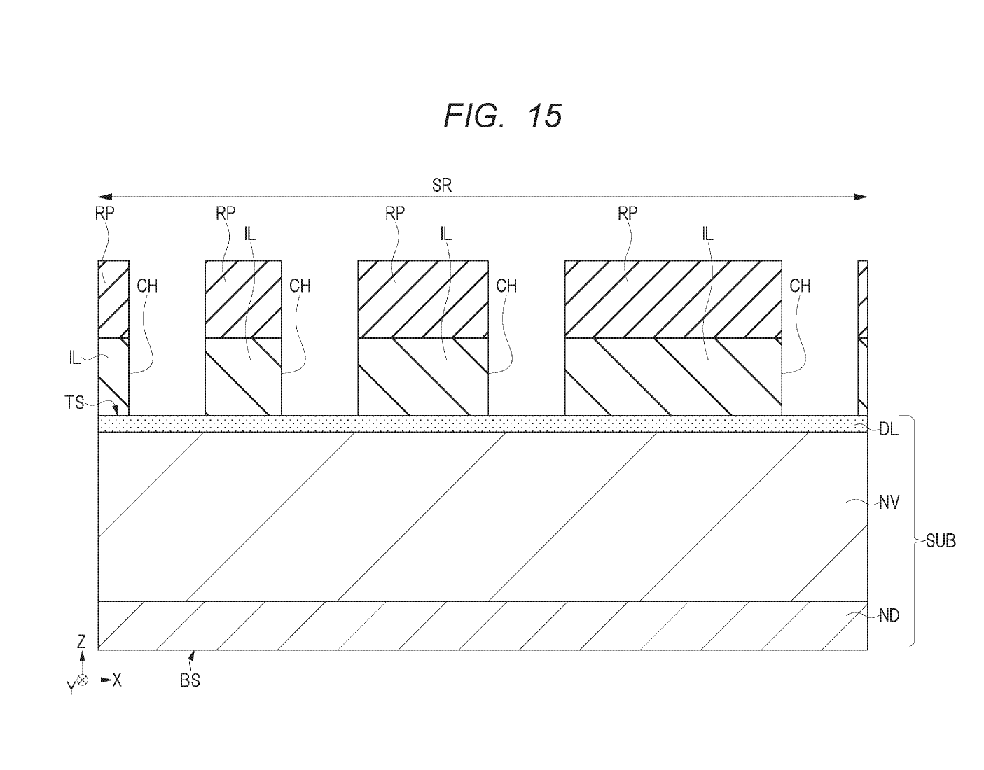

As shown in FIGS. 14 and 15, by performing an etching process on the interlayer insulating film IL using the resist pattern RP as a mask, the plurality of holes CH is formed in the interlayer insulating film IL. In the cell region CR, the hole CH is formed to reach the source region NS and the high-concentration diffusion region PR. In the scribe area SR, the hole CH is formed to reach the diffusion layer DL. Thereafter, the resist pattern RP is removed by ashing.

The width W and the width L of the plurality of holes CH (plurality of contacts CT) are determined by the pattern shape of the exposure mask MK or an exposure amount of the photolithography process. For example, the widths L1, L2 and L3 shown in FIGS. 4 and 5 can be adjusted by methods such as changing the opening pattern of the exposure mask MK or changing the exposure amount.

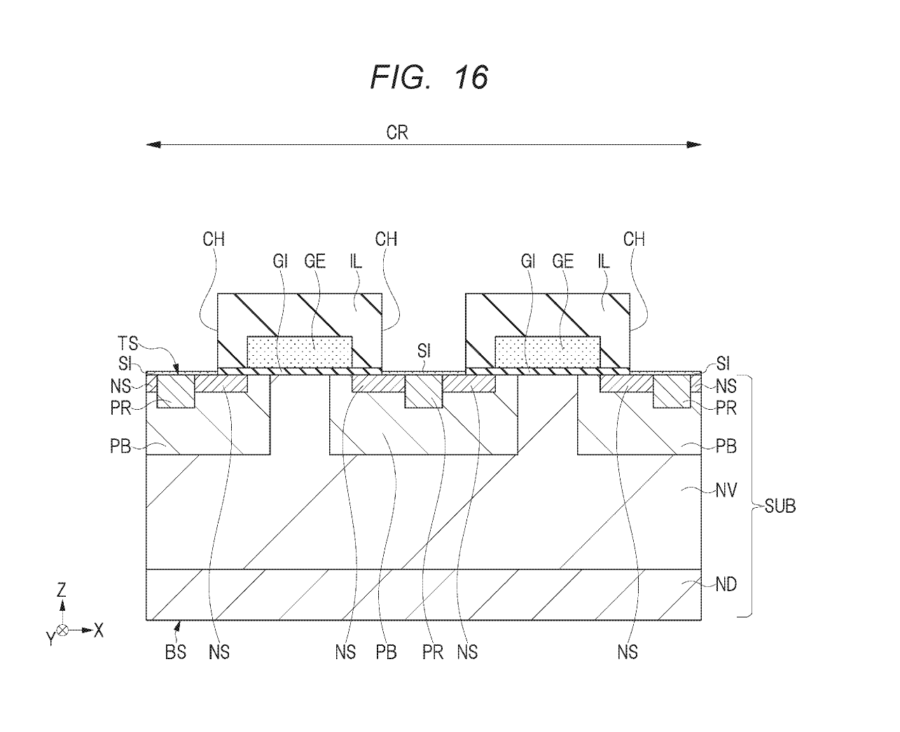

As shown in FIG. 16, a silicide film SI is formed at a bottom of the plurality of holes CH by Salicide (Self Aligned Silicide) technique. First, a metal film is formed inside the plurality of holes CH and on the interlayer insulating film IL by a film forming process using a sputtering method. This metal film is made of, for example, nickel, cobalt, or titanium. Next, by performing heat treatment, the silicon contained in the semiconductor substrate SUB and the metal film are reacted. As a result, the silicide film SI is formed on the source region NS, the high-concentration diffusion region PR, and the diffusion layer DL. Thereafter, the unreacted metal film is removed.

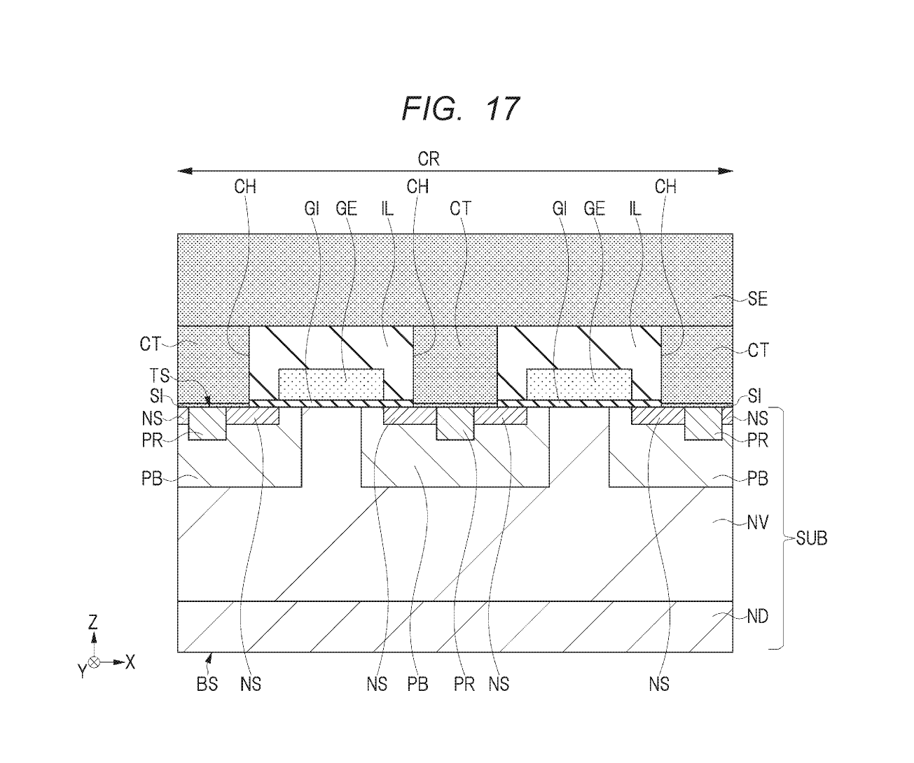

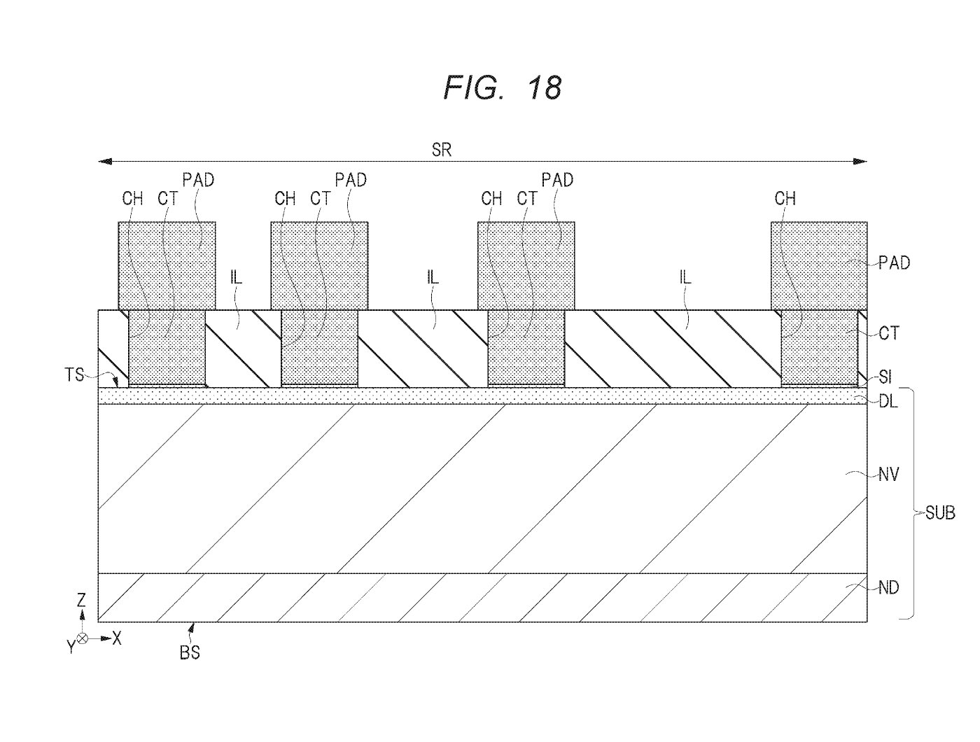

As shown in FIGS. 17 and 18, first, the first conductive film is formed on the interlayer insulating film IL by a film forming process using a sputtering method or a CVD method so as to fill the insides of the plurality of holes CH. The first conductive film is, for example, the above-mentioned first barrier metal film and first metal film. Next, by performing polishing processing using anisotropic etching or a CMP method, the first conductive film located outside the plurality of holes CH is removed. As a result, the plurality of contacts CT is formed inside the plurality of holes CH.

The plurality of contacts CT formed in the scribe area SR include the contacts CT1, CT2, and CT3 of the evaluation patterns TEG1, TEG2 and TEG3 (see FIGS. 4 and 5).

Next, the second conductive film is formed on the interlayer insulating film IL by a film forming process using a sputtering method or a CVD method. The second conductive film is, for example, the above-mentioned second barrier metal film and second metal film. Next, by patterning the second conductive film, a source electrode SE is formed in the cell region CR, and the plurality of pad electrodes PAD are formed in the scribe area SR.

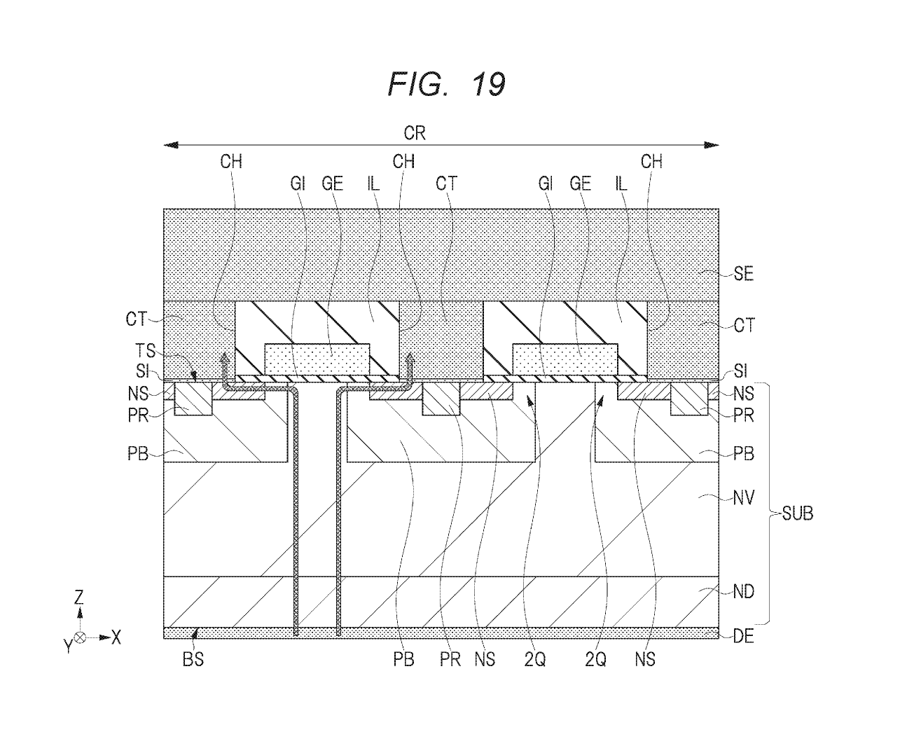

As shown in FIG. 19, a drain electrode DE is formed under the bottom surface BS of the semiconductor substrate SUB by a film forming process using, for example, a sputtering method. The drain electrode DE is formed of, for example, a single-layer metal film such as an aluminum film, a titanium film, a nickel film, a gold film, or a silver film, or a laminated film containing these metal films as appropriate. The drain electrode DE is formed across the entire bottom surface BS of the semiconductor substrate SUB (see FIG. 5).

Thus, the evaluation element 1Q and the MOSFET 2Q are formed in the semiconductor chip CHP1.

In the body region PB, the area located below the gate electrode GE via the gate dielectric film GI and between the drift region NV and the source region NS becomes the channel region of the MOSFET 2Q. As shown by the arrow in FIG. 19, a current path of the MOSFET 2Q extends from the drain electrode DE through the drain region ND, the drift region NV, the above-mentioned channel region, the source region NS, the silicide film SI, and the contact CT, reaching the source electrode SE.

In the cell region CR, if the width L of the contact CT becomes smaller than the propagation length LT, the contact resistance RCL increases, leading to an increase in an on-resistance of the MOSFET 2Q. By feeding back the value of the propagation length LT determined by the above-mentioned monitoring method of the propagation length LT to each manufacturing process, the increase in the on-resistance of the MOSFET 2Q can be suppressed.

For example, in the manufacturing processes shown in FIG. 9 and FIG. 10, a dose amount of ions when forming the source region NS can be adjusted (increased) according to the determined value of the propagation length LT, thereby reducing the diffusion resistance RDL and the contact resistance RCL. Additionally, in the manufacturing processes shown in FIG. 12 and FIG. 13, the pattern shape of the exposure mask MK or the exposure amount of the photolithography process to the resist material RS can be adjusted according to the determined value of the propagation length LT, so that the width L of the contact CT becomes larger than the determined propagation length LT. By performing at least one of these methods, the increase in the on-resistance of the MOSFET 2Q can be suppressed, and the performance of the semiconductor device (semiconductor chip CHP1) can be improved.

Furthermore, feedback to each manufacturing process may not be performed, and the determined propagation length LT may be treated as an index. For example, as long as it is within the requirements of the product specifications, the increase in on-resistance may be tolerated, and the width L of the contact CT may be reduced to achieve miniaturization of the MOSFET 2Q.

Although the present invention has been described in detail based on the embodiments, the present invention is not limited to these embodiments and can be variously modified without departing from the gist thereof.

What is claimed is:

1. A semiconductor device including an evaluation element, wherein the evaluation element comprising:
a diffusion layer formed in a semiconductor substrate;
an interlayer insulating film formed on the diffusion layer;
a pair of first contacts, a pair of second contacts, and a pair of third contacts formed in the interlayer insulating film and electrically connected to the diffusion layer, wherein
the first contacts are separated each other by a first distance in a first direction,
the second contacts are separated each other by the first distance in the first direction,
the third contacts are separated each other by the first distance in the first direction,
each of the first contacts have a first width in the first direction,
each of the second contacts have a second width in the first direction,
each of the third contacts have a third width in the first direction,
the third width is smaller than the second width, and
the second width is smaller than the first width.

2. The semiconductor device according to claim 1, wherein
the semiconductor substrate is made of a wide bandgap semiconductor with a bandgap wider than silicon.

3. The semiconductor device according to claim 1, wherein
the semiconductor substrate is made of a material including silicon carbide, gallium nitride, gallium oxide, or diamond.

4. The semiconductor device according to claim 1, wherein
the pair of first contacts, the pair of second contacts and the pair of third contacts are formed by filling a conductive film inside a plurality of holes formed in the interlayer insulating film,
the plurality of holes is formed by performing an etching process on the interlayer insulating film by using a resist pattern as a mask,
the resist pattern is formed by performing a photolithography process on a resist material by using an exposure mask, and
the first width, the second width and the third width are determined by a pattern shape of the exposure mask.

5. The semiconductor device according to claim 1, wherein
the pair of first contacts, the pair of second contacts and the pair of third contacts are formed by filling a conductive film inside a plurality of holes formed in the interlayer insulating film,
the plurality of holes is formed by performing an etching process on the interlayer insulating film by using a resist pattern as a mask,
the resist pattern is formed by performing a photolithography process on a resist material by using an exposure mask, and
the first width, the second width and the third width are determined by an exposure amount in the photolithography process.

6. The semiconductor device according to claim 1, wherein
the first distance is 5 micrometers or more.

7. The semiconductor device according to claim 1, wherein
the evaluation element is formed on the interlayer insulating film and further includes a plurality of pad electrodes electrically connected to the pair of first contacts, the pair of second contacts and the pair of third contacts.

8. The semiconductor device according to claim 1, wherein
the evaluation element is formed in the interlayer insulating film and further includes a plurality of first contacts, a plurality of second contacts and a plurality of third contacts electrically connected to the diffusion layer,
the plurality of first contacts include the pair of first contacts and are formed such that a distance between two adjacent first contacts in the first direction is different,
the plurality of second contacts include the pair of second contacts and are formed such that a distance between two adjacent second contacts in the first direction is different, and
the plurality of third contacts include the pair of third contacts and are formed such that a distance between two adjacent third contacts in the first direction is different.

9. A method for monitoring a propagation length by using the semiconductor device according to claim 1, comprising the step of:
measuring a first electrical resistance of a path from one of the first contacts to the other of the first contacts via the diffusion layer, a second electrical resistance of a path from one of the second contacts to the other of the second contacts via the diffusion layer and a third electrical resistance of a path from one of the third contacts to the other of the third contacts via the diffusion layer,
if there is a change in the first electrical resistance and the second electrical resistance, determining that the propagation length is smaller than the first width and larger than the second width,
if there is no change in the first electrical resistance and the second electrical resistance, and no change in the second electrical resistance and the third electrical resistance, determining that the propagation length is smaller than the third width, and
if there is no change in the first electrical resistance and the second electrical resistance and there is a change in the second electrical resistance and the third electrical resistance, determining that the propagation length is smaller than the second width and larger than the third width.

10. A method of manufacturing a semiconductor device using for a monitoring method of the propagation length according to claim 9, comprising the steps of:
(a) forming a source region in the semiconductor substrate by performing an ion implantation process;
(b) forming the interlayer insulating film on the semiconductor substrate;
(c) forming a resist material on the interlayer insulating film;
(d) forming a resist pattern by performing a photolithography process on the resist material using an exposure mask;
(e) forming a plurality of holes reaching the source region in the interlayer insulating film by performing an etching process using the resist pattern as a mask;
(f) forming a plurality of fourth contacts in the interlayer insulating film by filling a conductive film inside the plurality of holes, wherein
at least one of a dose amount of the ion implantation process when forming the source region, a pattern shape of the exposure mask and an exposure amount in the photolithography process is adjusted according to a value of the propagation length determined by the monitoring method of the propagation length.
